(19) United States
(12) Patent Application Publication
(10) Pub. No.: US 2017/0322771 A1
(43) Pub. Date: Nov. 9, 2017

(54) Configurable Processor with In-Package Look-Up Table

(71) Applicant: ChengDu HaiCun IP Technology LLC, ChengDU (CN)

(72) Inventor: Guobiao ZHANG, Corvallis, OR (US)

(73) Assignee: ChengDu HaiCun IP Technology LLC, ChengDu (CN)

(21) Appl. No.: 15/588,642

(22) Filed: May 6, 2017

(30) Foreign Application Priority Data
May 6, 2016 (CN) 201610301645.8
May 5, 2017 (CN) 201710310865.1

(51) Int. Cl. G06F 7/498; H03K 19/177; H01L 25/065

(52) U.S. Cl. CPC G06F 7/4988; H03K 19/1776; H03K 19/17728; H01L 25/0657; H01L 2225/06513; H01L 2225/06541

(57) ABSTRACT

The present invention discloses a configurable processor with an in-package look-up table. The configurable processor comprises a programmable memory die and a logic die located in a same package. The programmable memory die comprises a look-up table circuit (LUT) for storing data related to a desired function. The logic die comprises an arithmetic logic circuit (ALC) for performing arithmetic operations on the data read out from the LUT.

### CROSS-REFERENCE TO RELATED APPLICATIONS

This application claims priority from Chinese Patent Application 201610301645.8, filed on May 6, 2016; Chinese Patent Application 201710310865.1, filed on May 5, 2017, in the State Intellectual Property Office of the People's Republic of China (CN), the disclosure of which are incorporated herein by references in their entireties.

### BACKGROUND

### 1. Technical Field of the Invention

The present invention relates to the field of integrated circuit, and more particularly to processors.

### 2. Prior Art

Conventional processors use logic-based computation (LBC), which realizes mathematical functions primarily with logic circuits (e.g. XOR circuit). Logic circuits are suitable for arithmetic operations (i.e. addition, subtraction and multiplication), but not for non-arithmetic functions (e.g. elementary functions, special functions). Non-arithmetic functions are computationally hard. Rapid and efficient realization of the non-arithmetic functions has been a major challenge.

For the conventional processors, only few basic non-arithmetic functions (e.g. basic algebraic functions and basic transcendental functions) are implemented by hardware and they are referred to as built-in functions. These built-in functions are realized by a combination of arithmetic operations and look-up tables. For example, U.S. Pat. No. 5,954,787 issued to Eun on Sep. 21, 1999 taught a method for generating sine/cosine functions using look-up tables; U.S. Pat. No. 9,207,910 issued to Azadet et al. on Dec. 8, 2015 taught a method for calculating a power function using look-up tables.

Realization of built-in functions is further illustrated in FIG. 1A. A conventional processor 00X generally comprises a logic circuit 100X and a memory circuit 200X. The logic circuit 100X comprises an arithmetic logic unit (ALU) for performing arithmetic operations, whereas the memory circuit 200X comprises a look-up table circuit (LUT) for storing data related to the built-in function. To achieve a desired precision, the built-in function is approximated to a polynomial of a sufficiently high order. The LUT 200X stores the coefficients of the polynomial; and the ALU 100X calculates the polynomial. Because the ALU 100X and the LUT 200X are formed side-by-side on a semiconductor substrate 00S, this type of horizontal integration is referred to as two-dimensional (2-D) integration.

The 2-D integration puts stringent requirements on the manufacturing process. As is well known in the art, the memory transistors in the LUT 200X are vastly different from the logic transistors in the ALC 100X. The memory transistors have stringent requirements on leakage current, while the logic transistors have stringent requirements on drive current. To form high-performance memory transistors and high-performance logic transistors on the same surface of the semiconductor substrate 00S at the same time is a challenge.

The 2-D integration also limits computational density and computational complexity. Computation has been developed towards higher computational density and greater computational complexity. The computational density, i.e. the computational power (e.g. the number of floating-point operations per second) per die area, is a figure of merit for parallel computation. The computational complexity, i.e. the total number of built-in functions supported by a processor, is a figure of merit for scientific computation. For the 2-D integration, inclusion of the LUT 200X increases the die size of the conventional processor 00X and lowers its computational density. This has an adverse effect on parallel computation. Moreover, because the ALU 100X, as the primary component of the conventional processor 00X, occupies a large die area, the LUT 200X, occupying only a small die area, supports few built-in functions. FIG. 1B lists all built-in transcendental functions supported by an Intel Itanium (IA-64) processor (referring to Harrison et al. “The Computation of Transcendental Functions on the IA-64 Architecture”, Intel Technical journal, Q4 1999, hereinafter Harrison). The IA-64 processor supports a total of 7 built-in transcendental functions, each using a relatively small LUT (from 0 to 24 kb) in conjunction with a relatively high-order Taylor series (from 5 to 22).

The LBC-based processor 00X suffers one drawback. Because different logic circuits are used to realize different built-in functions, the processor 00X is fully customized. In other words, once its design is complete, the processor 00X can only realize a fixed set of pre-defined built-in functions. Apparently, configurable computation is more desirable, where a same hardware can realize different mathematical functions under the control of a set of configuration signals.

In the past, configurable logic, i.e. a same hardware realizes different logics under the control of a set of configuration signals, was realized by configurable gate array (e.g. field-programmable gate array). U.S. Pat. No. 4,870,302 issued to Freeman on Sep. 26, 1989 (hereinafter Freeman) discloses a configurable gate array. It comprises an array of configurable logic elements and a hierarchy of configurable interconnects that allow the configurable logic elements to be wired together. In the prior-art configurable gate arrays, mathematical functions are still realized in fixed computing elements, which are part of hard blocks and not configurable, i.e. the circuits realizing these mathematical functions are fixedly connected and are not subject to change by programming. Apparently, fixed computing elements would limit further applications of the configurable gate array. To overcome this difficulty, the present invention expands the original concept of the configurable gate array by making the fixed computing elements configurable.

### Objects and Advantages

It is a principle object of the present invention to realize configurable computation.

It is a further object of the present invention to realize field-configurable computation.

It is a further object of the present invention to realize reconfigurable computation.

It is a further object of the present invention to realize configurable computation for multi-variable functions.

It is a further object of the present invention to provide a configurable processor with a greater computational complexity.

It is a further object of the present invention to provide a configurable processor with a higher computational density.

It is a further object of the present invention to provide a field-programmable gate array (FPGA) with a greater computational flexibility.

In accordance with these and other objects of the present invention, the present invention discloses a configurable processor with an in-package look-up table.

### SUMMARY OF THE INVENTION

The present invention discloses a configurable processor with an in-package look-up table (IP-LUT) (i.e. IP-LUT configurable processor). The IP-LUT configurable processor comprises a logic die and a programmable memory die. The logic die comprises at least an arithmetic logic circuit (ALC) and is referred to as an ALC die, whereas the programmable memory die comprises at least a look-up table circuit (LUT) and is referred to as an LUT die. The LUT stores data related to a function (e.g. the look-up table for this function), while the ALC performs arithmetic operations on the data read out from the LUT. The ALC die and LUT die are located in a same package and they are communicatively coupled by a plurality of inter-die connections. Located in the same package as the ALC, the LUT is referred to as in-package LUT (IP-LUT). Because it is programmable, the IP-LUT can realize a desired function by writing the data related to the desired function (e.g. the look-up table for the desired function) into the IP-LUT, thus realizing configurable computation.

The IP-LUT configurable processor uses memory-based computation (MBC), which realizes mathematical functions primarily with the LUT. Compared with the LUT used by the conventional processor, the IP-LUT used by the IP-LUT configurable processor has a much larger capacity. Although arithmetic operations are still performed, the MBC only needs to calculate a polynomial to a lower order because it uses a larger IP-LUT as a starting point for computation. For the MBC, the fraction of computation done by the IP-LUT could be more than the ALC.

Each usage cycle of the IP-LUT configurable processor comprises two stages: a configuration stage and a computation stage. In the configuration stage, the data related to a desired function is written into the IP-LUT. In the computation stage, the desired function is realized by reading the function-related data from the IP-LUT. The IP-LUT configurable processor can realize field-configurable computation and reconfigurable computation. For the field-configurable computation, the IP-LUT configurable processor can realize a desired function in the field of use by writing the data related to the desired function into the IP-LUT in the field of use. For reconfigurable computation, the IP-LUT comprises at least a reprogrammable memory array and the IP-LUT configurable processor can realize different functions by writing different data related to different functions (e.g. the look-up tables for different functions) into the IP-LUT during different usage cycles. For example, during a first usage cycle, the IP-LUT stores data related to a first function; during a second usage cycle, the IP-LUT stores data related to a second function.

Because the ALC die and the LUT die are located in a same package, this type of vertical integration is referred to as 2.5-D integration. The 2.5-D integration has a profound effect on the computational density and computational complexity. For the conventional 2-D integration, the footprint of a conventional processor 00X is roughly equal to the sum of those of the ALU 100X and the LUT 200X. On the other hand, because the 2.5-D integration moves the LUT from aside to above, the IP-LUT configurable processor becomes smaller and computationally more powerful. In addition, the total LUT capacity of the conventional processor 00X is less than 100 kb, whereas the total IP-LUT capacity for the IP-LUT configurable processor could reach 100 Gb. Consequently, a single IP-LUT configurable processor could support as many as 10,000 built-in functions (including various types of complex functions), far more than the conventional processor 00X. Furthermore, because the ALC die and the LUT die are separate dice, the logic transistors in the ALC die and the memory transistors in the LUT die are formed on separate semiconductor substrates. Consequently, their manufacturing processes can be individually optimized.

To further improve programmability, the present invention further discloses an IP-LUT configurable gate array. It comprises an array of configurable computing elements, an array of configurable logic elements and an array of configurable interconnects. The IP-LUT comprises at least a programmable memory array which stores data related to a function (e.g. the look-up table for the function). Because it is programmable, the IP-LUT can realize a desired function by writing the data related to the desired function into the IP-LUT, thus realizing configurable computation. The configurable logic elements and configurable interconnects in the IP-LUT configurable gate array are similar to those in the conventional configurable gate array. During computation, a complex function is first decomposed into a combination of basic functions. Each basic function is then realized by an associated configurable computing element. Finally, the complex function is realized by configuring the corresponding configurable logic elements and configurable interconnects.

Accordingly, the present invention discloses a configurable processor, comprising: a programmable memory die comprising a look-up table circuit (LUT) for storing data related to a desired function; a logic die comprising an arithmetic logic circuit (ALC) for performing arithmetic operations on said data; a plurality of inter-die connections for communicatively coupling said memory die and said logic die; wherein said memory die and said logic die are located in a same package.

### BRIEF DESCRIPTION OF THE DRAWINGS

FIG. 1A is a schematic view of a conventional processor (prior art); FIG. 1B lists all transcendental functions supported by an Intel Itanium (IA-64) processor (prior art);

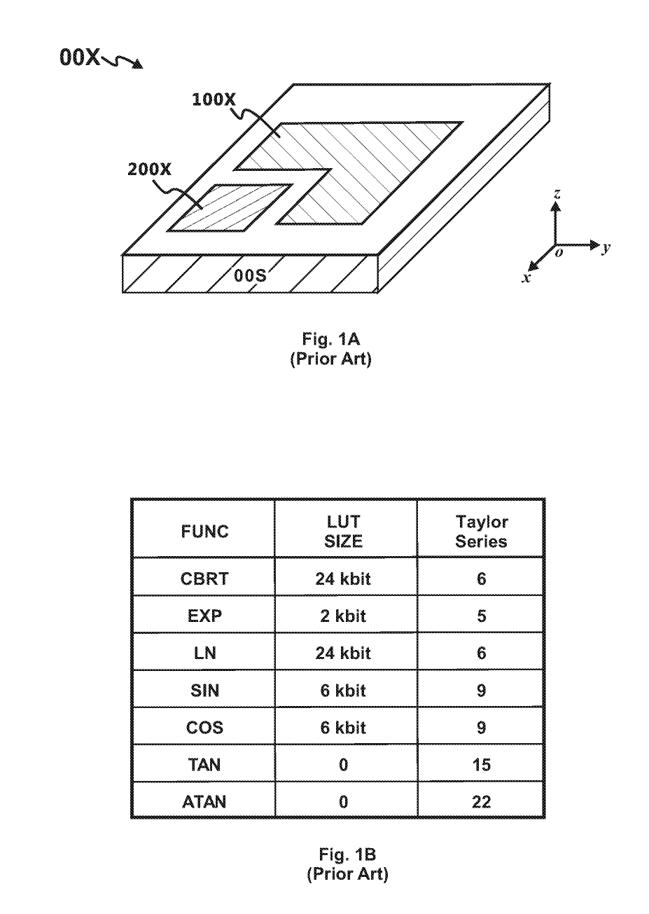

FIG. 2A is a simplified block diagram of a typical IP-LUT configurable processor;

FIG. 2B is a perspective view of its front side; FIG. 2C is a perspective view of its backside;

FIGS. 3A-3C are the cross-sectional views of three preferred IP-LUT configurable processors;

FIG. 4A is a simplified block diagram of a typical configurable computing element; FIG. 4B is a block diagram of a preferred configurable computing element realizing a single-precision function; FIG. 4C lists a preferred set of LUT size and Taylor series required to realize functions with different precisions;

FIG. 5 is a block diagram of a preferred IP-LUT configurable gate array;

FIG. 6 is a block diagram of the preferred IP-LUT configurable gate array realizing a multi-variable function, i.e. e=a·sin(b)+c·cos(d).

It should be noted that all the drawings are schematic and not drawn to scale. Relative dimensions and proportions of parts of the device structures in the figures have been shown exaggerated or reduced in size for the sake of clarity and convenience in the drawings. The same reference symbols are generally used to refer to corresponding or similar features in the different embodiments. The symbol “/” means a relationship of “and” or “or”. Throughout the present invention, both “look-up table” and “look-up table circuit” are abbreviated to LUT. Based on context, the LUT may refer to a look-up table or a look-up table circuit.

### DETAILED DESCRIPTION OF THE PREFERRED EMBODIMENTS

Those of ordinary skills in the art will realize that the following description of the present invention is illustrative only and is not intended to be in any way limiting. Other embodiments of the invention will readily suggest themselves to such skilled persons from an examination of the within disclosure.

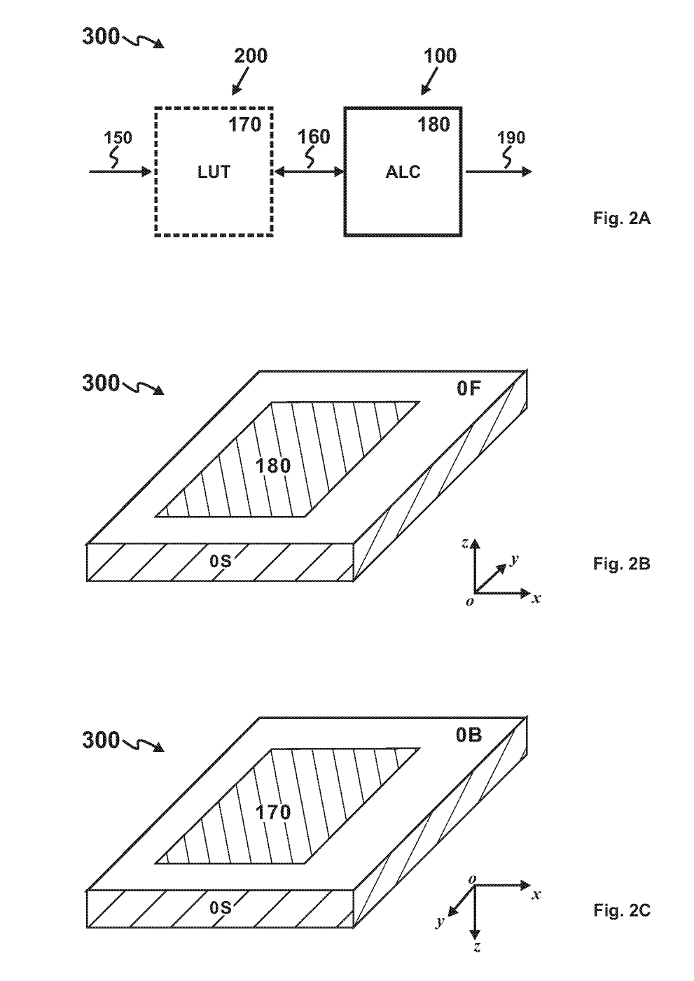

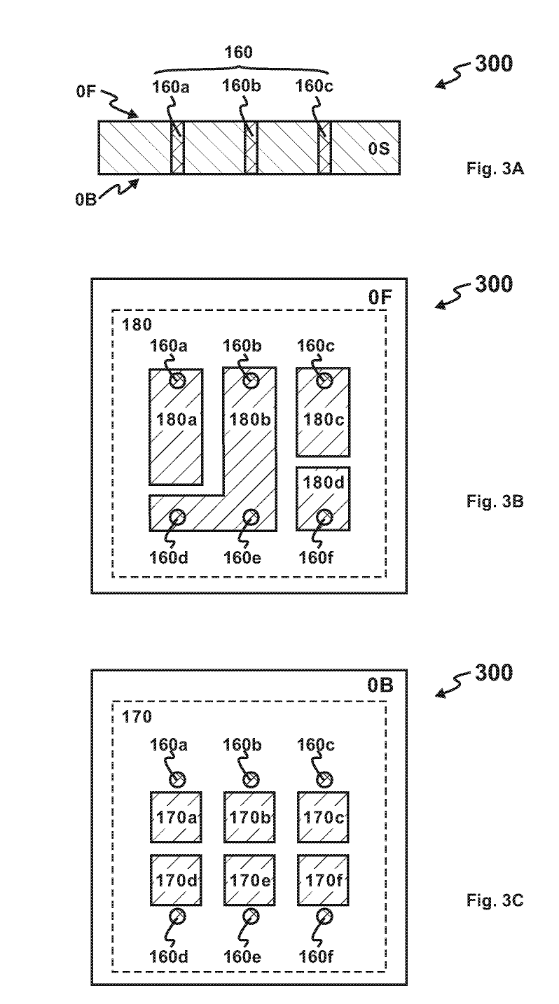

Referring now to FIG. 2A-2B, a typical IP-LUT configurable processor 300 is disclosed. The IP-LUT configurable processor 300 has one or more inputs 150, and one or more outputs 190. The IP-LUT configurable processor 300 further comprises a logic die 100 and a programmable memory die 200. The logic die 100 is formed on a first semiconductor substrate 100S and comprises at least an arithmetic logic circuit (ALC) 180. Accordingly, the logic die 100 is also referred to as an ALC die. On the other hand, the programmable memory die 200 is formed on a second semiconductor substrate 200S and comprises at least a look-up table circuit (LUT). Accordingly, the programmable memory die 200 is also referred to as an LUT die. The LUT 170 stores data related to a function (e.g. the look-up table for this function), while the ALC 180 performs arithmetic operations on the data read out from the LUT 170. The ALC die 100 and LUT die 200 are located in a same package and they are communicatively coupled by a plurality of inter-die connections 160. Located in the same package as the ALC 180, the LUT 170 is referred to as in-package LUT (IP-LUT). Because it is programmable, the IP-LUT 170 can realize a desired function by writing the data related to the desired function into the IP-LUT 170, thus realizing configurable computation. In this preferred embodiment, the LUT die 200 is stacked on the ALC die 100, with the IP-LUT 170 and the ALC 180 at least partially overlapping. Because they are formed on separate dice, the IP-LUT 170 is represented by dashed lines and the ALC 180 is represented by solid lines throughout the present invention.

The IP-LUT configurable processor 300 uses memory-based computation (MBC), which realizes mathematical functions primarily with the IP-LUT 170. Compared with the LUT 200X used by the conventional processor 00X, the IP-LUT 170 used by the IP-LUT configurable processor 300 has a much larger capacity. Although arithmetic operations are still performed, the MBC only needs to calculate a polynomial to a lower order because it uses a larger IP-LUT 170 as a starting point for computation. For the MBC, the fraction of computation done by the IP-LUT 170 could be more than the ALC 180.

Each usage cycle of the IP-LUT configurable processor 300 comprises two stages: a configuration stage and a computation stage. In the configuration stage, the data related to a desired function is written into the IP-LUT 170. In the computation stage, the desired function is realized by reading the function-related data from the IP-LUT 170. The IP-LUT configurable processor 300 can realize field-configurable computation and reconfigurable computation. For the field-configurable computation, the IP-LUT configurable processor 300 can realize a desired function in the field of use by writing the data related to the desired function into the IP-LUT 170 in the field of use. For reconfigurable computation, the IP-LUT 170 comprises at least a reprogrammable memory array and the IP-LUT configurable processor 300 can realize different functions by writing different data related to different functions (e.g. the look-up tables for different functions) into the IP-LUT 170 during different usage cycles. For example, during a first usage cycle, the IP-LUT 170 stores data related to a first function; during a second usage cycle, the IP-LUT 170 stores data related to a second function.

The IP-LUT 170 may use a RAM or a ROM. The RAM includes SRAM and DRAM. The ROM includes OTP, EPROM, EEPROM and flash memory. The flash memory can be categorized into NOR and NAND, and the NAND can be further categorized into horizontal NAND and vertical NAND. For the reconfigurable computation, the IP-LUT 170 uses a reprogrammable memory. For the field-configurable computation, besides the reprogrammable memory, the IP-LUT 170 may also use an OTP. On the other hand, the ALC 180 may comprise an adder, a multiplier, and/or a multiply-accumulator (MAC). It may perform integer operation, fixed-point operation, or floating-point operation.

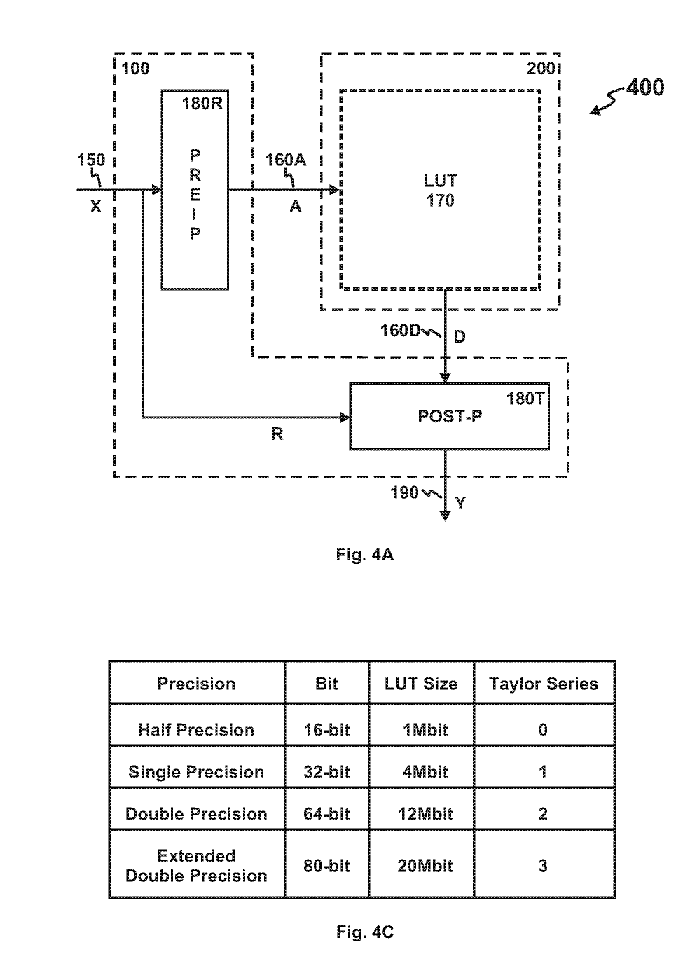

Referring now to FIGS. 3A-3C, the cross-sectional views of three preferred IP-LUT configurable processors 300 are shown. These preferred embodiments are located in multi-chip packages (MCP). Among them, the IP-LUT configurable processor 300 in FIG. 3A comprises two separate dice: an ALC die 100 and an LUT die 200. The dice 100, 200 are stacked on the package substrate 110 and located in a same package 130. Micro-bumps 116 act as the inter-die connections 160 and provide electrical coupling between the dice 100, 200. In this preferred embodiment, the LUT die 200 is stacked on the ALC die 100; the LUT die 200 is flipped and bonded face-to-face with the ALC die 100. Alternatively, the ALC die 100 may be stacked on the LUT die 200; either die does not have to be flipped.

The IP-LUT configurable processor 300 in FIG. 3B comprises an ALC die 100, an interposer 120 and an LUT die 200. The interposer 120 comprise a plurality of through-silicon vias (TSV) 118. The TSVs 118 provide electrical couplings between the ALC die 100 and the LUT die 200, offer more freedom in design and facilitate heat dissipation. In this preferred embodiment, the TSVs 118 and the micro-bumps 116 collectively form the inter-die connections 160.

The IP-LUT configurable processor 300 in FIG. 3C comprises an ALC die 100, and at least two LUT dice 200A, 200B. These dice 100, 200A, 200B are separate dice and located in a same package 130. Among them, the LUT die 200B is stacked on the LUT die 200A, while the LUT die 200A is stacked on the ALC die 100. The dice 100, 200A, 200B are electrically coupled with the TSVs 118 and the micro-bumps 116. Apparently, the IP-LUT 170 in FIG. 3C has a large capacity than that in FIG. 3A. Similarly, the TSVs 118 and the micro-bumps 116 collectively form the inter-die connections 160.

Because the ALC die 100 and the LUT die 200 are located in a same package, this type of vertical integration is referred to as 2.5-D integration. The 2.5-D integration has a profound effect on the computational density and computational complexity. For the conventional 2-D integration, the footprint of a conventional processor 00X is roughly equal to the sum of those of the ALU 100X and the LUT 200X. On the other hand, because the 2.5-D integration moves the LUT from aside to above, the IP-LUT configurable processor 300 becomes smaller and computationally more powerful. In addition, the total LUT capacity of the conventional processor 00X is less than 100 kb, whereas the total IP-LUT capacity for the IP-LUT configurable processor 300 could reach 100 Gb. Consequently, a single IP-LUT configurable processor 300 could support as many as 10,000 built-in functions (including various types of complex functions), far more than the conventional processor 00X. Moreover, the 2.5-D integration can improve the communication throughput between the IP-LUT 170 and the ALC 180. Because they are physically close and coupled by a large number of inter-die connections 160, the IP-LUT 170 and the ALC 180 have a larger communication throughput than the LUT 200X and the ALU 100X in the conventional processor 00X. Lastly, the 2.5-D integration benefits manufacturing process. Because the ALC die 100 and the LUT die 200 are separate dice, the logic transistors in the ALC die 100 and the memory transistors in the LUT die 200 are formed on separate semiconductor substrates. Consequently, their manufacturing processes can be individually optimized.

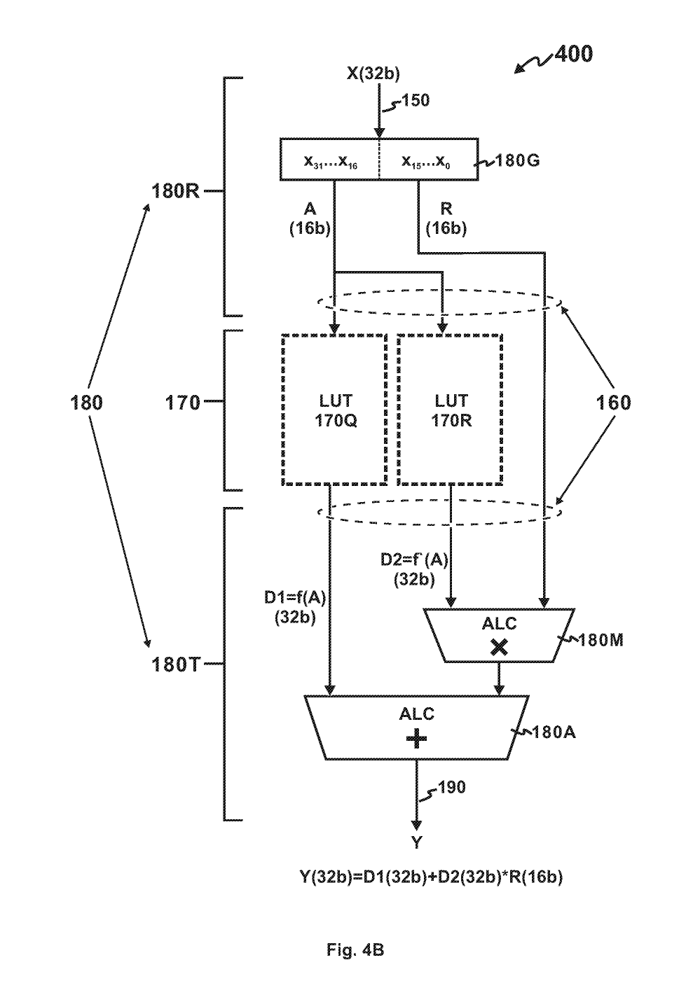

To further improve programmability, the present invention further discloses an IP-LUT configurable gate array 700 (FIG. 4A-6). It comprises an array of configurable computing elements 400AA . . . , an array of configurable logic elements 500AA . . . and an array of configurable interconnects 610-650 . . . FIG. 4A shows a typical configurable computing element 400. It comprises a pre-processing circuit 180R, a post-processing circuit 180T and at least an IP-LUT 170. The IP-LUT 170 comprises a programmable memory array which stores data related to a function (e.g. the look-up table for the function). Because it is programmable, the IP-LUT 170 can realize a desired function by writing the data related to the desired function into the IP-LUT 170, thus realizing configurable computation. The pre-processing circuit 180R converts the input variable (X) 150 into an address (A) 160A of the IP-LUT 170. After the data (D) 160D at the address (A) is read out from the IP-LUT 170, the post-processing circuit 180T converts it into the function value (Y) 190. A residue (R) of the input variable (X) is fed into the post-processing circuit 180T to improve the computational precision. In this example, the pre-processing circuit 180R and the post-processing circuit 180T are formed in the logic die 100. Alternatively, a portion of the pre-processing circuit 180R and the post-processing circuit 180T may be formed in the memory die 200.

FIG. 4B shows a preferred configurable computing element 400 realizing a single-precision function Y=f(X). The IP-LUT 170 comprises two LUTs 170Q, 170R with 2 Mb capacity each (16-bit input and 32-bit output): the LUT 170Q stores the function value D1=f(A), while the LUT 170R stores the first-order derivative value D2=f′(A). The ALC 180 comprises a pre-processing circuit 180R (mainly comprising an address buffer) and a post-processing circuit 180T (comprising an adder 180A and a multiplier 180M). The inter-die connections 160 transfer data between the ALC 180 and the IP-LUT 170. During computation, a 32-bit input variable X (x₃₁ . . . x₀) is sent to the IP-LUT configurable processor 300 as an input 150. The pre-processing circuit 180R extracts the higher 16 bits (x₃₁ . . . x₁₆) and sends it as a 16-bit address input A to the IP-LUT 170. The pre-processing circuit 180R further extracts the lower 16 bits (x₁₅ . . . x₀) and sends it as a 16-bit input residue R to the post-processing circuit 180T. The post-processing circuit 180T performs a polynomial interpolation to generate a 32-bit output value Y 190. In this case, the polynomial interpolation is a first-order Taylor series: Y(X)=D1+D2*R=f(A)+f′(A)*R. Apparently, a higher-order polynomial interpolation (e.g. higher-order Taylor series) can be used to improve the computational precision.

When realizing a built-in function, combining the LUT with polynomial interpolation can achieve a high precision without using an excessively large LUT. For example, if only LUT (without any polynomial interpolation) is used to realize a single-precision function (32-bit input and 32-bit output), it would have a capacity of 2³²*32=128 Gb. By including polynomial interpolation, significantly smaller LUTs can be used. In the above embodiment, a single-precision function can be realized using a total of 4 Mb LUT (2 Mb for the function values, and 2 Mb for the first-derivative values) in conjunction with a first-order Taylor series. This is significantly less than the LUT-only approach (4 Mb vs. 128 Gb).

FIG. 4C lists a preferred set of LUT size and Taylor series required to realize functions with different precisions. It uses a range-reduction method taught by Harrison. For the half precision (16 bit), the required IP-LUT capacity is 2¹⁶*16=1 Mb and no Taylor series is needed; for the single precision (32 bit), the required IP-LUT capacity is 2¹⁶*32*2=4 Mb and a first-order Taylor series is needed; for the double precision (64 bit), the required IP-LUT capacity is 2¹⁶*64*3=12 Mb and a second-order Taylor series is needed; for the extended double precision (80 bit), the required IP-LUT capacity is 2¹⁶*80*4=20 Mb and a third-order Taylor series is needed. To those skilled in the art, other combinations of LUT size and Taylor series can be used to optimize the LUT usage and arithmetic operations.

Besides elementary functions, the preferred embodiment of FIGS. 4A-4B can be used to implement non-elementary functions such as special functions. Special functions can be defined by means of power series, generating functions, infinite products, repeated differentiation, integral representation, differential difference, integral, and functional equations, trigonometric series, or other series in orthogonal functions. Important examples of special functions are gamma function, beta function, hyper-geometric functions, confluent hyper-geometric functions, Bessel functions, Legrendre functions, parabolic cylinder functions, integral sine, integral cosine, incomplete gamma function, incomplete beta function, probability integrals, various classes of orthogonal polynomials, elliptic functions, elliptic integrals, Lame functions, Mathieu functions, Riemann zeta function, automorphic functions, and others. The IP-LUT configurable processor will simplify the computation of special functions and promote their applications in scientific computation.

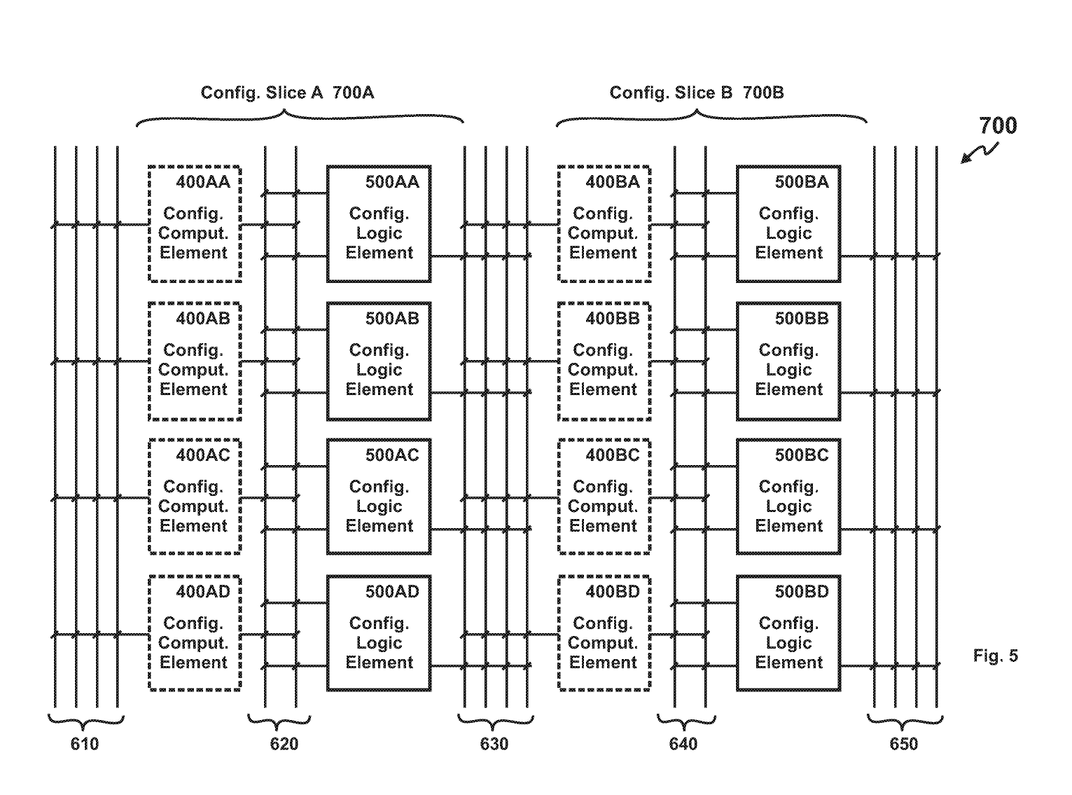

FIG. 5 shows a preferred IP-LUT configurable gate array 700. It comprises first and second configurable slices 700A, 700B. Each configurable slice (e.g. 700A) comprises a first array of configurable computing elements (e.g. 400AA-400AD) and a second array of configurable logic elements (e.g. 500AA-500AD). A configurable channel 620 is placed between the first array of configurable computing elements (e.g. 400AA-400AD) and the second array of configurable logic elements (e.g. 500AA-500AD). The configurable channels 610, 630, 650 are also placed between different configurable slices 700A, 700B. The configurable channels 610-650 comprise an array of configurable interconnects (represented by slashes at the cross-points in each configurable channel). For those skilled in the art, besides configurable channels, sea-of-gates may also be used. The configurable logic elements and the configurable interconnects are similar to those disclosed in Freeman (U.S. Pat. No. 4,870,302). Each configurable logic element can selectively realize any one of a plurality of logic operations (including shift, logic NOT, logic AND, logic OR, logic NOR, logic NAND, logic XOR, addition “+”, and subtraction “−”). Each configurable interconnect can selectively couple or de-couple at least one interconnect line. In some preferred embodiments, at least one configurable logic element comprises at least a multiplier.

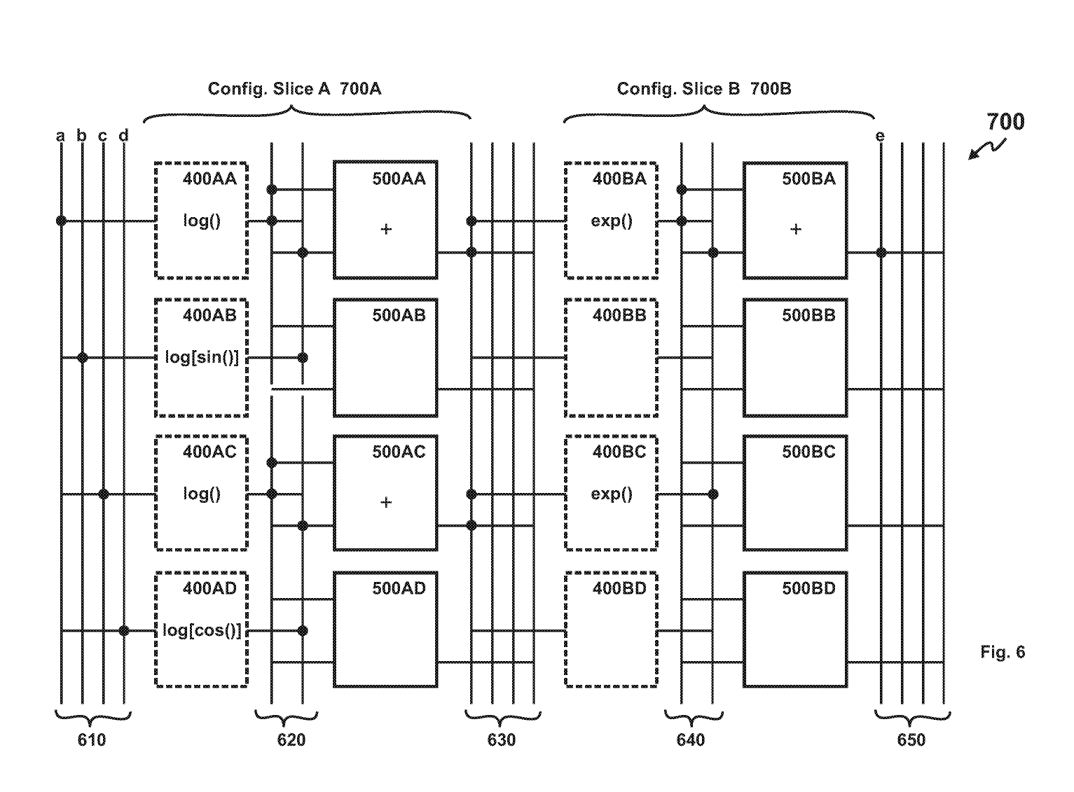

FIG. 6 discloses an instantiation of the preferred IP-LUT configurable gate array implementing a multi-variable function, i.e. e=a·sin(b)+c·cos(d). The configurable interconnects in the configurable channel 610-650 use the same convention as Freeman: the interconnect with a dot means that the interconnect is connected; the interconnect without dot means that the interconnect is not connected; a broken interconnect means that two broken sections are un-coupled. In this preferred implementation, the configurable computing element 400AA is configured to realize the function log( ) whose result log(a) is sent to a first input of the configurable logic element 500A. The configurable computing element 400AB is configured to realize the function log [sin( )], whose result log [sin(b)] is sent to a second input of the configurable logic element 500A. The configurable logic element 500A is configured to realize addition, whose result log(a)+log [sin(b)] is sent the configurable computing element 100BA. The configurable computing element 400BA is configured to realize the function exp( ), whose result exp{log(a)+log [sin(b)]}=a·sin(b) is sent to a first input of the configurable logic element 500BA. Similarly, through proper configurations, the results of the configurable computing elements 400AC, 400AD, the configurable logic elements 500AC, and the configurable computing element 400BC can be sent to a second input of the configurable logic element 500BA. The configurable logic element 500BA is configured to realize addition, whose result a·sin(b)+c·cos(d) is sent to the output e. Apparently, by changing its configuration, the configurable gate array 700 can realize other complex functions.

The BS-LUT configurable gate array 700 is particularly suitable for realizing multi-variable functions. If only LUT is used to realize the above 4-variable function, i.e. e=a·sin(b)+c·cos(d), an enormous LUT is needed: 2¹⁶*2¹⁶*2¹⁶*2¹⁶*16=256 Eb even for half precision, which is impractical. Using the BS-LUT configurable gate array 700, only 8 Mb LUT (including 8 configurable computing elements, each with 1 Mb capacity) is needed to realize a 4-variable function. To those skilled in the art, the BS-LUT configurable gate array 700 can be used to realize other multi-variable functions.

While illustrative embodiments have been shown and described, it would be apparent to those skilled in the art that many more modifications than that have been mentioned above are possible without departing from the inventive concepts set forth therein. For example, the processor could be a micro-controller, a central processing unit (CPU), a digital signal processor (DSP), a graphic processing unit (GPU), a network-security processor, an encryption/decryption processor, an encoding/decoding processor, a neural-network processor, or an artificial intelligence (AI) processor. These processors can be found in consumer electronic devices (e.g. personal computers, video game machines, smart phones) as well as engineering and scientific workstations and server machines. The invention, therefore, is not to be limited except in the spirit of the appended claims.

What is claimed is:

1. A configurable processor, comprising:
a programmable memory die comprising a look-up table circuit (LUT) for storing data related to a desired function;
a logic die comprising an arithmetic logic circuit (ALC) for performing arithmetic operations on said data;
a plurality of inter-die connections for communicatively coupling said memory die and said logic die;
wherein said memory die and said logic die are located in a same package.

2. The configurable processor according to claim 1, wherein said programmable memory die comprises a RAM.

3. The configurable processor according to claim 1, wherein said programmable memory die comprises a ROM.

4. The configurable processor according to claim 1, wherein said programmable memory die comprises a reprogrammable memory.

5. The configurable processor according to claim 4, wherein said LUT stores different data related to different functions during different usage cycles.

6. The configurable processor according to claim 5, wherein:
said LUT stores data related to a first function during a first usage cycle; and
said LUT stores data related to a second function during a second usage cycle.

7. The configurable processor according to claim 1, wherein said configurable processor is a configurable gate array.

8. The configurable processor according to claim 7, wherein said configurable gate array comprises a plurality of configurable computing elements.

9. The configurable processor according to claim 8, wherein each of said configurable computing elements comprises a programmable memory array for storing said data for said function.

10. The configurable processor according to claim 8, wherein each of said configurable computing elements comprises a pre-processing circuit.

11. The configurable processor according to claim 8, wherein each of said configurable computing elements comprises a post-processing circuit.

12. The configurable processor according to claim 7, wherein said configurable gate array comprises a plurality of configurable logic elements.

13. The configurable processor according to claim 12, wherein each of said configurable logic elements selectively realizes any one of a plurality of logic operations including shift, logic NOT, logic AND, logic OR, logic NOR, logic NAND, logic XOR, addition, subtraction and multiplication.

14. The configurable processor according to claim 7, wherein said configurable gate array comprises a plurality of configurable interconnects.

15. The configurable processor according to claim 14, wherein each of said configurable interconnects selectively couples or de-couples at least one interconnect line.

16. The configurable processor according to claim 1, wherein said memory die and said logic die are vertically stacked.

17. The configurable processor according to claim 1, wherein said inter-die connections comprise micro-bumps.

18. The configurable processor according to claim 1, wherein said inter-die connections comprise through-silicon vias (TSV).

19. The configurable processor according to claim 1, further comprising another programmable memory die comprising another LUT.

20. The configurable processor according to claim 19, wherein said memory die and said another memory die are vertically stacked.
